(19) United States
(12) Patent Application Publication
(10) Pub. No.: US 2002/0151096 A1
(43) Pub. Date: Oct. 17, 2002

(54) Method for preventing metal adhesion during facet coating

(76) Inventors: Robert A. Baron, Mohrsville, PA (US); Mark B. Cholewa, Mt. Penn Township, PA (US); G. Jacob Fox IV, Allentown, PA (US); Kevin J. Sullivan, New Tripoli, PA (US)

Correspondence Address: DICKSTEIN SHAPIRO MORIN & OSHINSKY LLP, 2101 L STREET NW, WASHINGTON, DC, 20037-1526, US

(21) Appl. No.: 09/832,857

(22) Filed: Apr. 12, 2001

(51) Int. Cl. H01L 21/00; H01L 33/00

(52) U.S. Cl. 438/38; 257/100

(57) ABSTRACT

A method of eliminating the use of spacers necessary for the conventional facet coating processing of laser bars is disclosed. A low temperature dielectric layer is provided on the back side of the semiconductor laser bar to prevent the metal from the solder/metal contacts from adhering to an adjacent laser bar during facet coating processing. In another embodiment, a low temperature dielectric layer is provided on the back side of the semiconductor laser bar and then patterned to form various alignment marks that provide contrast for the subsequent identification and alignment of the laser bar in an automated bonding vision system.

### FIELD OF THE INVENTION

The present invention relates to the field of semiconductor devices and, in particular, to a method for uniform and precise handling of semiconductor laser bars so that metal adhesion is prevented during facet coating operations.

### BACKGROUND OF THE INVENTION

Semiconductor laser devices, such as laser diodes and photodetectors, are formed from semiconductor wafer substrates. During fabrication, solder pads of a solder material, for example gold (Au) and/or a tin-gold (AuSn) alloy, are first formed on the top surface of the wafer substrate, or on both the top and bottom surfaces of the wafer substrate to facilitate subsequent bonding processes. Subsequent to the formation of the solder pads and/or metal contacts, the wafer substrate is cleaved into bars of semiconductor material, which in turn may be further cleaved into discrete semiconductor laser chips.

Following the cleave process, each end face or facet of each semiconductor laser bar is coated with an optical coating material in a facet coating apparatus. The facet coating process is carried out in a high-vacuum deposition chamber and requires the semiconductor laser bars to be placed on edge and be held together in a facet coating fixture for depositing the optical coating material or materials only on the desired facets of the laser bar. The existing fixtures of the facet coating apparatuses require the laser bars to be held in a very compact and small area. Thus, because of the minimal distance between adjacent laser bars in the facet coating apparatus, the gold or solder material from the solder pads located on the top and/or bottom of each semiconductor laser bar will adhere to the unprotected and uncovered portions of the semiconductor substrate of adjacent semiconductor laser bars.

Various attempts have been made to minimize the above-identified problems. For example, stainless steel or silicon spacers have been inserted in between semiconductor laser bars during the facet coating process to avoid the metal adhesion during this process. FIG. 1 illustrates, for example, a conventional facet coating fixture 10 for retaining and holding a plurality of semiconductor laser bars 12 during a facet coating operation. A plurality of spacers 14 are provided on each side of each semiconductor laser bar 12 so that the semiconductor laser bars 12 are separated but sandwiched together on the facet coating fixture 10.

Although the use of spacers, such as spacers 14 of FIG. 1, provide a more uniform deposition of the facet coating material, a major disadvantage is that the spacers are one-time-use items. Another disadvantage is that, by using spacers, the capacity of the facet coating fixture is cut in half. This means that, a facet coating fixture that could hold up to twenty semiconductor laser bars, for example, will be able to hold only ten semiconductor laser bars intertwined with ten spacers, when spacers are used. Another disadvantage is that the insertion of the spacers between adjacent laser bars requires an individual, typically an operator, to use a weighted object or her/his fingers to manually place the spacers on the facet coating fixture and then to subsequently disengage and remove the spacers from the fixture at the completion of the facet coating process. This method, however, cannot guarantee uniform adhesion and/or removal of the spacers from the facet coating fixture and, as a result, parts may detach and be damaged during the process. In addition, because of the fragility of the laser bars, the pressure magnitude during the attaching and detaching of the spacers is not constant and the operators can damage the laser bars, reducing the yield of usable laser bars.

Accordingly, there is a need for an improved method for handling the laser bars during the facet coating operation. There is also a need for preventing the solder/gold areas from adhering to adjacent unprotected substrate portions during a facet coating operation, as well as a method of increasing the overall yield of usable laser bars.

### BRIEF SUMMARY OF THE INVENTION

The present invention eliminates the use of spacers necessary in the conventional facet coating processing of laser bars. A low temperature dielectric layer is provided on the back side of the semiconductor laser bar to prevent the metal from the solder/metal bonding pads from adhering to an adjacent laser bar during facet coating processing. In another embodiment, a low temperature dielectric layer is provided on the back side of the semiconductor laser bar and then patterned to form various alignment marks that allow subsequent identification and alignment of the laser bar in an automated bonding vision system.

These and other advantages and features of the invention will be more clearly understood from the following detailed description of the invention which is provided in connection with the accompanying drawings.

### BRIEF DESCRIPTION OF THE DRAWINGS

FIG. 1 illustrates a schematic view of a conventional facet coating fixture holding ten semiconductor laser bars and ten spacers.

FIG. 2 illustrates a cross-sectional view of a semiconductor photodetector device formed in accordance with a first embodiment of the present invention.

FIG. 3 illustrates the semiconductor photodetector device of FIG. 2 at a stage of processing subsequent to that shown in FIG. 2.

FIG. 4 illustrates a schematic view of a facet coating fixture holding semiconductor photodetector devices formed in accordance with the present invention.

FIG. 5 illustrates a schematic side-by-side view of a facet coating fixture holding semiconductor photodetector devices formed in accordance with the present invention and that of a conventional facet coating fixture.

FIG. 6 illustrates a cross-sectional view of a semiconductor photodetector device formed in accordance with a second embodiment of the present invention.

FIG. 7 illustrates the semiconductor photodetector device of FIG. 6 at a stage of processing subsequent to that shown in FIG. 6.

FIG. 8 illustrates the semiconductor photodetector device of FIG. 6 at a stage of processing subsequent to that shown in FIG. 7.

FIG. 9 illustrates a bottom view of the semiconductor photodetector device of FIG. 8.

FIG. 10 illustrates a top view of the semiconductor photodetector device of FIG. 8.

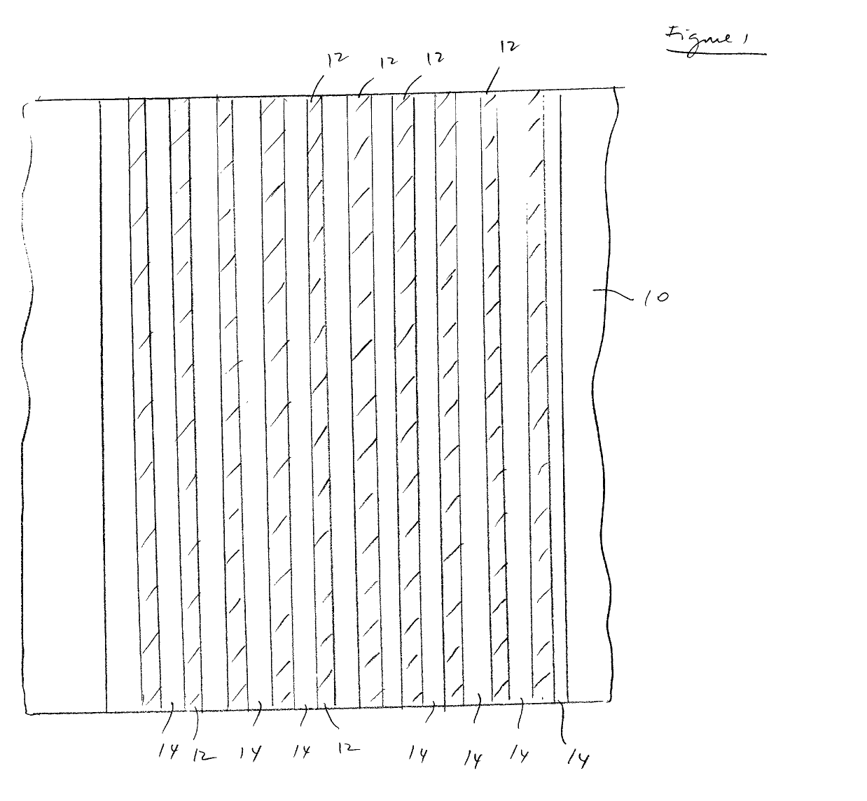

### DETAILED DESCRIPTION OF THE INVENTION

In the following detailed description, reference is made to various specific embodiments in which the invention may be practiced. These embodiments are described with sufficient detail to enable those skilled in the art to practice the invention, and it is to be understood that other embodiments may be employed, and that structural, electrical and methodology changes may be made and equivalents substituted without departing from the invention. Accordingly, the following detailed description is not to be taken in a limiting sense and the scope of the present invention is defined by the appended claims.

The term “solder” as used herein is intended to include not only a combination of layers of gold (Au) and gold/tin (AuSn), but any other gold/tin combination or gold/tin alloy combination, or any combination between gold or gold alloy with other metals or materials as known in the semiconductor art, as long as such solder is conductive. In addition, the term “solder” as used herein is intended to include any alloys of tin and lead with or without traces of materials such as aluminum, antimony, arsenic, bismuth, cadmium, copper, indium, iron, nickel, silver or zinc. Furthermore, the term “solder” is intended to include any conductive structure formed by depositing successive layers of materials, for example titanium tungsten, nickel, gold, tin, silver, palladium, indium and/or their alloys, among many others, over designated solder pad areas.

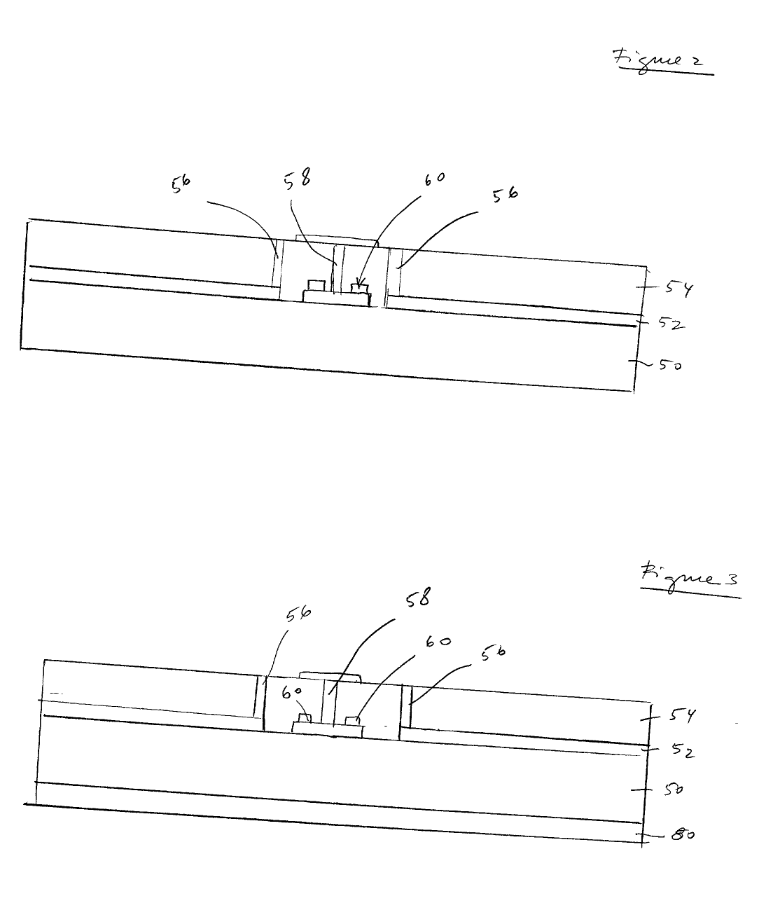

Referring now to the drawings, where like elements are designated by like reference numerals, FIGS. 2-10 illustrate embodiments of semiconductor laser devices 100, 200 (FIG. 3, FIG. 8) formed according to the present invention. FIG. 2 depicts a portion of a semiconductor laser bar comprising a semiconductor device formed over a semiconductor substrate 50 which has an indium phosphate (InP) layer 52, typically an n-InP layer, formed overlying the semiconductor substrate 50. An active layer 58 is epitaxially grown in an insulating layer 54, which is formed over the n-InP layer 52, as also shown in FIG. 2. The insulating layer 54 may be formed by deposition and may include silicon oxide, borophosphosilicate glass (BPSG), borosilicate glass (BSG) or tetraethylortho silicate (TEOS), among others. Also illustrated in FIG. 2 are alignment features 56 for aligning the n- or p- type contacts 60, typically formed of gold (Au), on the same side of the semiconductor device, if the device is a photodetector, or on opposite sides of the device, if the device is a laser, for example.

It must be noted that, although the Metal Organic Vapor Phase Epitaxy (MOVPE) method is preferred for the formation of the n-InP layer 52 and the active layer 58, a Liquid Phase Epitaxy (LPE) method, a Vapor Phase Epitaxy (VPE) method, or a Molecular Beam Epitaxy (MBE) could also be used as an alternative. As known in the art, the active layer 58 should be capable of absorbing, emitting, amplifying, or modulating light, depending on the particular type of optoelectronic device. Thus, if the semiconductor device of FIG. 2 is a photodetector, the active layer 58 would correspond to a detector for detecting light that is sampled.

Although the embodiments described below will illustrate a photodetector device, such as the photodetector device 100 of FIG. 3, it must be understood that the present invention is not limited to this semiconductor optical device and other optical devices such as laser diodes, DFB lasers, modulators and amplifiers, among others, may be used also, as long as their formation requires a facet coating operation. Thus, the term “laser bar” as used in the present invention refers to bars including semiconductor optoelectronic devices not limited to lasers.

Also, although the present invention refers to an exemplary n-type substrate on which operative layers form an n-p junction around an active area, it is to be understood that the present invention also contemplates a p-type substrate on which a corresponding p-n junction is formed around an active area.

Referring now to FIG. 3, a dielectric layer 80 is formed on the back side of the semiconductor device of FIG. 2 to complete the formation of the photodetector device 100. For the purposes of the present invention, a “back side” of the semiconductor device is defined as the side of the semiconductor device which is opposite to the side on which the active devices, such as the active layer 58 of FIG. 2, are formed. In an exemplary embodiment of the invention, the dielectric layer 80 is formed by plasma enhanced chemical vapor deposition (PECVD) at a temperature between about 100° C. to about 200° C. and to a thickness of about 2,000 Angstroms to about 10,000 Angstroms, more preferably to a thickness of about 3,000 Angstroms. Although PECVD is preferred, other known deposition methods, such as sputtering by chemical vapor deposition, physical vapor deposition or blanket deposition by spin coating, may be used also in accordance with the characteristics of the semiconductor optical devices already formed.

The dielectric layer 80 may be formed of a conventional insulator, for example a thermal oxide of silicon, such as silicon oxide (SiO or SiO₂) or a nitride, such as silicon nitride (Si₃N₄). Alternatively, a low dielectric inorganic material such as, for example, polyimide, spin-on-polymers (SOP), parylene, flare, polyarylethers, polytetrafluoroethylene, benzocyclobutene (BCB), SILK, fluorinated silicon oxide (FSG), NANOGLASS or hydrogen silsesquioxane, among others, may be used also, as desired. The present invention is not limited, however, to the above-listed materials and other insulating and/or dielectric materials known in the industry may be used also. In fact, an advantage of the present invention is that the nature of the dielectric material is not crucial, but it is desirable that the formation of the dielectric layer 80 takes place in an ambient with a temperature lower than about 200° C. This limitation is desirable because, as known in the art and as explained below, during the fabrication of a laser device, such as a laser or photodetector, the wafer undergoes a thinning process. This process, also known in the art as lapping, takes a relatively thick laser wafer and reduces it to a desired thickness. Currently, laser wafers are reduced to a thickness of approximately four mils (i.e., four-one thousandth of an inch).

In accordance with an embodiment of the invention, the thinning process takes place prior to the formation of the dielectric layer 80. To perform the thinning process, the laser wafer is mounted onto a wafer support. The wafer support is typically a sapphire disk, but it can also be quartz or a metal plate. Wax is used as an adhesive to ensure that the laser wafer adheres to and remains mounted on the wafer support. Once mounted, the laser wafer and the wafer support are inserted into a thinning or lapping apparatus where the laser wafer is mechanically or chemically reduced to the desired thickness. Once the laser wafer is thinned, the laser wafer, which is still affixed to the support, is removed from the apparatus and the deposition of the dielectric layer 80 takes place. Thus, the presence of wax makes desirable the use of a low temperature deposition for the dielectric layer 80 formed subsequent to the thinning process. For the purposes of this embodiment, a low temperature deposition is defined as a temperature between about 10° C. to about 200° C., more preferably of about 25° C. to about 125° C.

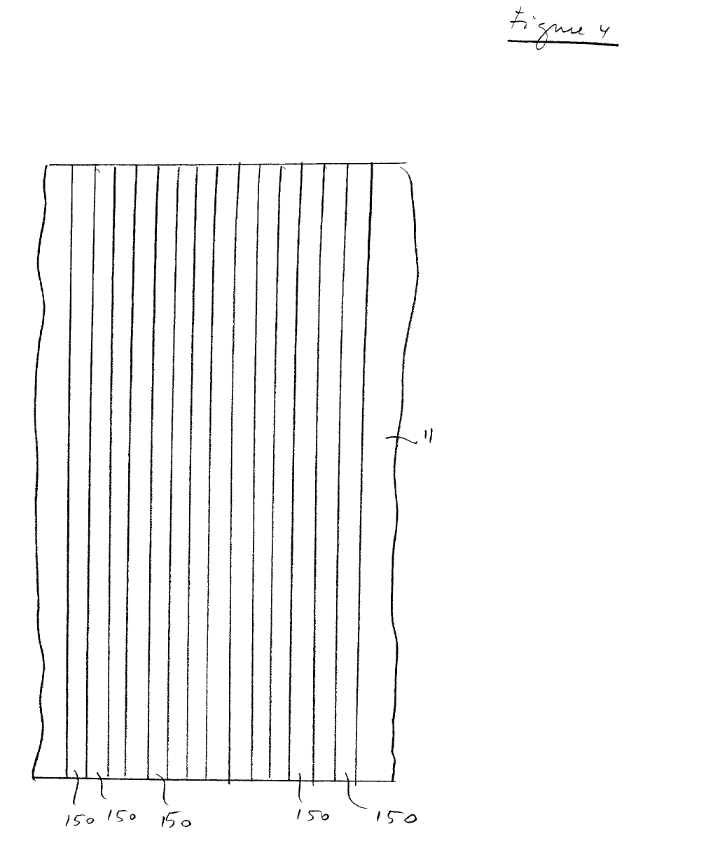

Although the embodiment of the present invention has been explained for simplicity with reference to the photodetector device 100 of FIG. 3, it must be understood that the dielectric layer 80 is formed over the whole laser wafer substrate which will be eventually cleaved into a plurality of semiconductor laser bars comprising optical devices such as photodetector device 100 of FIG. 3. As known in the art, a whole wafer substrate will contain about ten semiconductor laser bars, each of the ten semiconductor laser bars further comprising photodetector devices 100. Fourteen semiconductor laser bars 150, each coated with the dielectric layer 80, are illustrated in FIG. 4 as being placed in a facet coating fixture 11 and ready for the facet coating operation.

By comparison, FIG. 5 illustrates a conventional facet coating fixture 10 holding ten semiconductor laser bars 12 and ten spacers 14, next to a facet coating fixture 11 holding fourteen semiconductor laser bars 150 formed according to the present invention. As illustrated in FIG. 5, the need of spacers between adjacent semiconductor bars is eliminated as the dielectric layer 80 offers protection from the solder material of the adjacent semiconductor bars.

Once the semiconductor laser bars 150 formed according to the present invention are placed in the facet coating fixture 11 of FIG. 5, the coating process may begin immediately. As such, the facet coating fixture 11 may be placed in a carrier frame mounted in a vacuum chamber provided with an electron beam source, for example, and various optical coating materials. As known in the art, heat lamps may be also provided to heat the vacuum chamber and minimize the water vapors from the walls of the vacuum chamber. The optical coating materials are electron beam evaporated in the vacuum chamber and onto the semiconductor laser bars 150 secured onto the facet coating fixture 11. The type, amount and deposition rate of optical coating depend on the type of semiconductor lasers that are being manufactured. The optical coating materials may comprise, for example, silicon, silicon dioxide, titanium oxide or cubic zirconia, or any other materials that will form the mirror facets of the semiconductor lasers.

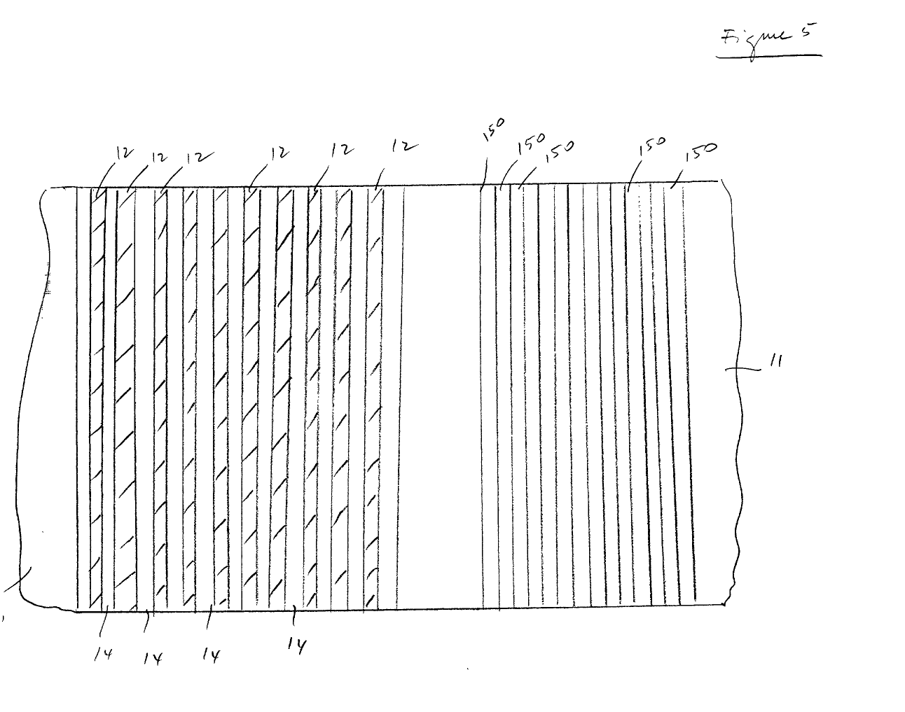

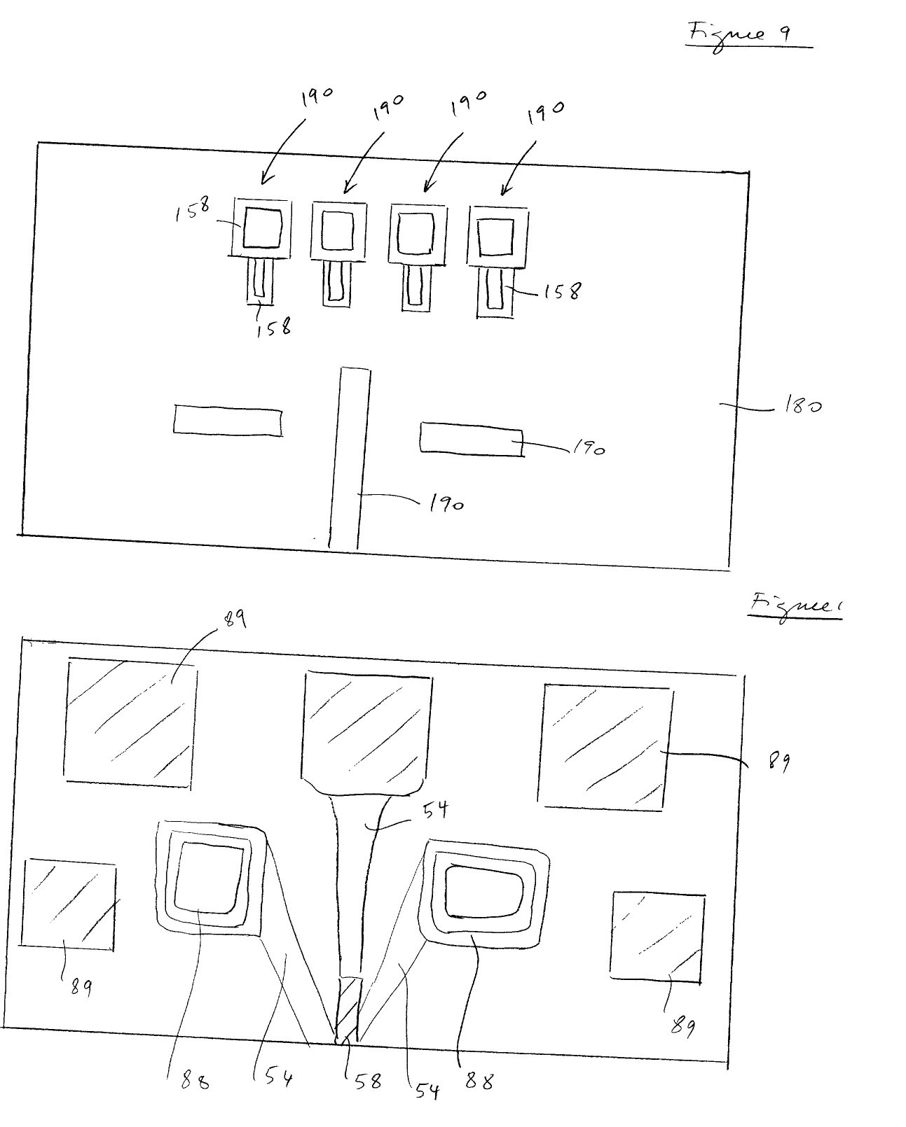

FIGS. 6-10 illustrate another embodiment of the present invention, according to which a semiconductor laser bar comprising a photodetector device 200 (FIG. 8) is formed according to the present invention. According to this embodiment, a dielectric layer 180 (FIGS. 6-8) is formed over the substrate 50 and is further patterned by a lithography technique, for example, to form various alignment patterns, such as alignment patterns 190 (FIG. 9), which give an optical vision system registry of the active devices formed on the wafer substrate.

The dielectric layer 180 of FIG. 6 may be formed of a conventional insulator, for example a thermal oxide of silicon, such as silicon oxide (SiO or SiO₂) or a nitride, such as silicon nitride (Si₃N₄). Alternatively, a low dielectric inorganic material such as, for example, polyimide, spin-on-polymers (SOP), parylene, flare, polyarylethers, polytetrafluoroethylene, benzocyclobutene (BCB), SILK, fluorinated silicon oxide (FSG), NANOGLASS or hydrogen silsesquioxane, among others, may be used also, as desired. The present invention is not limited, however, to the above-listed materials and other insulating and/or dielectric materials known in the industry may be used also. As explained above with reference to the formation of the dielectric layer 80 (FIG. 3), a desirable limitation for the dielectric layer 180 is that its formation takes place in a low temperature ambient so that the laser wafer could comply with the thinning process requirements.

A photoresist layer 155 is formed over the dielectric layer 180, as also shown in FIG. 6. The photoresist layer 155 is exposed through a mask 156 (FIG. 6) with high-intensity UV light. The mask 156 may include any suitable pattern of opaque and clear regions that may depend, for example, on the desired pattern to be formed in the dielectric layer 180. This way, portions 155a of the photoresist layer 155 are exposed through portions 156a of the mask 156 wherever portions of the dielectric layer 180 need to be removed.

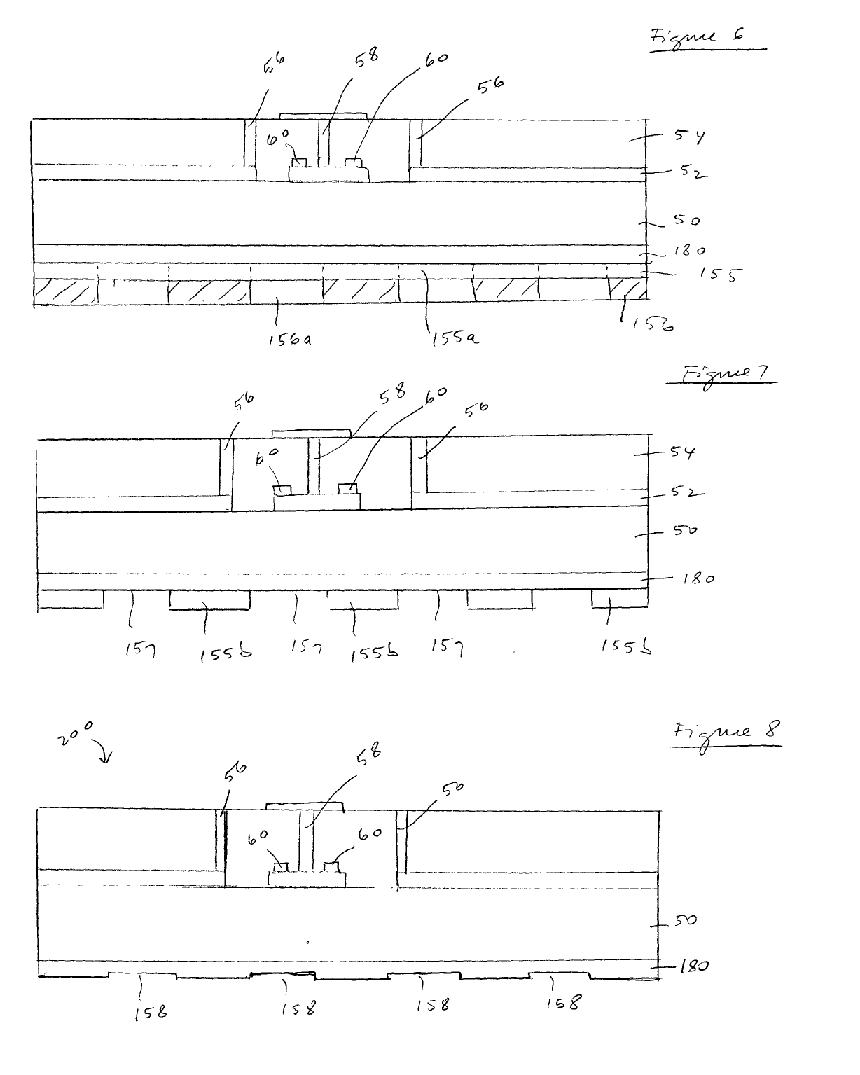

Although FIG. 6 schematically illustrates mask 156 positioned over the photoresist layer 155, those skilled in the art will appreciate that mask 156 is typically spaced from the photoresist layer 155 and light passing through mask 156 is focussed onto the photoresist layer 155. After exposure and development of the exposed portions 155a, portions 155b of the unexposed and undeveloped photoresist are left over the dielectric layer 180, as shown in FIG. 7. This way, openings 157 (FIG. 7) are formed in the photoresist layer 155.

An etch step is next performed to obtain grooves 158 (FIGS. 8-9) in the dielectric layer 180 and to complete the formation of a semiconductor wafer comprising a photodetector device 200 formed according to the present invention. The grooves 158 (FIG. 8) are etched to a depth of about 500 Angstroms to about 2,000 Angstroms, more preferably of about 1,000 Angstroms. Subsequent to the formation of the grooves 158, the remaining portions 155b (FIG. 7) of the positive photoresist layer 155 are then removed by chemicals, such as hot acetone or methylethylketone, or by flooding the substrate 50 with UV irradiation to degrade the remaining portions 155b to obtain the photodetector device 200 of FIG. 8.

The grooves 158 are patterned and etched into the dielectric layer 180 to form a variety of alignment features 190, shown in FIG. 9. For simplicity, FIG. 9 illustrates a bottom view of the structure of FIG. 8 with only seven alignment features 190. It must be understood, however, that a semiconductor wafer substrate comprises thousands of such alignment features. After the semiconductor wafer substrate is cleaved into a plurality of laser bars, each of the individual laser bars will retain only few of such alignment features.

The alignment features 190 of FIG. 9 act as alignment marks for a vision system, for example an automated bonding vision system that identifies a laser bar and positions it on an optical sub-assembly (OSA) for subsequent bonding operations. The alignment features 190 give the automated bonding vision system registry for the front side devices, that are the devices located on the opposite side of the alignment features 190. Such an opposite side of the alignment features 190 is illustrated in FIG. 10, which is also a top view of the structure of FIG. 8. Schematically illustrated in FIG. 10 are two MIM capacitors 88, active layer 58 and five solder pads 89. Because the dielectric layer 180 covers more than 75% of the surface area of the back side of the laser wafer substrate, as shown in FIG. 9, when the wafers are loaded into a facet coating fixture, the dielectric material 180 will prevent gold from the solder pads 89 of one laser bar from adhering to the substrate of an adjacent laser bar.

While the invention has been described and illustrated with reference to specific embodiments, the present invention is not limited to the details of the specific embodiments. Accordingly, the above description and drawings are only to be considered illustrative of exemplary embodiments which achieve the features and advantages of the present invention. Modifications and substitutions to specific process conditions and structures can be made without departing from the spirit and scope of the present invention. Accordingly, the invention is not to be considered as being limited by the foregoing description and drawings, but is only limited by the scope of the appended claims.

What is claimed as new and desired to be protected by Letters Patent of the United States is:

1. A method of preventing metal adhesion among adjacent bars located in a facet coating fixture, said method comprising the steps of:
providing at least a first bar of semiconductor optoelectronic devices, said first bar having a first top surface and a first bottom surface, said first top surface being on the opposite side of said first bottom surface;
forming a dielectric material over said first bottom surface of said first bar;
locating said first bar in said facet coating fixture; and
locating at least a second bar of semiconductor optoelectronic devices in said facet coating fixture and adjacent to said first bar, said second bar having a second top surface and a second bottom surface, and said second top surface being adjacent to said dielectric material of said first bar.

2. The method of claim 1, wherein said dielectric material is a low temperature dielectric material.

3. The method of claim 1, wherein an active area of said first bar is provided adjacent said first top surface.

4. The method of claim 1 further comprising the step of forming alignment features in said dielectric material.

5. The method of claim 4, wherein said alignment features are formed by etching said dielectric layer.

6. The method of claim 1, wherein said first and second bars are laser bars.

7. A method of facet coating at least one semiconductor laser bar located in a facet coating fixture, said method comprising the steps of:
providing at least a first semiconductor laser bar, said first semiconductor laser bar having a first top surface and a first bottom surface, said first top surface being on the opposite side of said first bottom surface;
forming a dielectric material over said first bottom surface of said first semiconductor laser bar;
locating said first semiconductor laser bar in said facet coating fixture;
locating at least a second semiconductor laser bar in said facet coating fixture and adjacent to said first semiconductor laser bar, said second semiconductor laser bar having a second top surface and a second bottom surface, and said second top surface being adjacent to said dielectric material of said first semiconductor laser bar; and
facet coating said at least first and second semiconductor laser bars.

8. The method of claim 7, wherein said dielectric material is a low temperature dielectric material.

9. The method of claim 7 further comprising the step of forming alignment features in said dielectric material.

10. The method of claim 9, wherein said alignment features are formed by etching said dielectric layer.

11. The method of claim 7, wherein said act of facet coating said first and second semiconductor laser bars further comprises facet coating a plurality of said semiconductor laser bars.

12. A method of processing laser bars, said method comprising the steps of:
providing a laser bar having a first surface and a second surface, at least one semiconductor optoelectronic device being provided adjacent said first surface, said first surface being on the opposite side of said second surface;
forming a dielectric layer over said second surface; and
forming at least one optical alignment feature in said dielectric layer.

13. The method of claim 12, wherein said step of forming said at least one alignment feature further comprises removing portions of said dielectric layer to form said at least one alignment feature.

14. The method of claim 12, wherein said dielectric layer is formed of a low temperature dielectric material.

15. The method of claim 12, wherein said dielectric layer is formed by deposition.

16. A bar containing at least one semiconductor optoelectronic device, said bar comprising:
a top surface having said at least one semiconductor optoelectronic device adjacent therein;
a bottom surface opposite to said top surface; and
a dielectric layer in contact with at least a portion of said bottom surface.

17. The bar of claim 16, wherein said dielectric layer comprises a low temperature dielectric material.

18. The bar of claim 16, wherein said dielectric layer is formed entirely over said bottom surface.

19. The bar of claim 16 further comprising at least one alignment feature formed in said dielectric layer.

20. The bar of claim 16 further comprising a layer of solder on said top surface of said bar.
